(19) United States
(12) Patent Application Publication
(10) Pub. No.: US 2026/0290408 A1
(43) Pub. Date: Sep. 24, 2026

(54) SEMICONDUCTOR MEMORY DEVICE

(71) Applicant: Kioxia Corporation, Tokyo (JP)

(72) Inventors: Nobuaki OKADA, Kawasaki Kanagawa (JP); Masaki UNNO, Fujisawa Kanagawa (JP); Hiroshi MAEJIMA, Setagaya Tokyo (JP)

(21) Appl. No.: 19/333,251

(22) Filed: Sep. 18, 2025

(30) Foreign Application Priority Data
Mar. 19, 2025 (JP) 2025-045686

(51) Int. Cl. G11C 5/06; G11C 16/04; H01L 23/00; H01L 25/18; H10B 41/10; H10B 41/27; H10B 41/35; H10B 41/41; H10B 43/10; H10B 43/27; H10B 43/35; H10B 43/40; H10D 80/30

(52) U.S. Cl. CPC G11C 5/063; G11C 16/0483; H10B 41/10; H10B 41/27; H10B 41/35; H10B 41/41; H10B 43/10; H10B 43/27; H10B 43/35; H10B 43/40; H10D 80/30; H10W 90/00; H10W 90/792

(57) ABSTRACT

A semiconductor memory device includes a first chip, a second chip, and a third chip. The first chip includes a plurality of first structures arranged in a first direction and including first memory cells, and a first bit line connected to the plurality of first structures. The second chip includes a plurality of second structures arranged in the first direction and including a plurality of second memory cells, a second bit line connected to the plurality of second structures, and a via contact electrode electrically connected to the first bit line and the second bit line. The third chip includes a first transistor electrically connected to the first bit line and the second bit line. One of the plurality of first structures is provided at a position overlapping the via contact electrode when viewed in a second direction and is able to store data.

### CROSS-REFERENCE TO RELATED APPLICATION(S)

This application is based upon and claims the benefit of priority from Japanese Patent Application No. 2025-045686, filed Mar. 19, 2025, the entire contents of which are incorporated herein by reference.

### FIELD

Embodiments described herein relate generally to a semiconductor memory device.

### BACKGROUND

A semiconductor memory device including a first chip, a second chip, and a third chip. Each of the first chip and the second chip includes a plurality of structures arranged in a first direction and each including a plurality of memory cells, and a bit line provided on one side of the plurality of structures in a second direction intersecting the first direction. The bit line extends in the first direction, and is connected to the plurality of structures. The third chip includes a transistor electrically connected to the bit line.

### BRIEF DESCRIPTION OF THE DRAWINGS

FIG. 1 is a schematic circuit diagram showing a configuration of a part of a semiconductor memory device according to a first embodiment.

FIG. 2 is a schematic circuit diagram showing a configuration of a part of the semiconductor memory device.

FIG. 3 is a schematic exploded perspective view showing a configuration example of the semiconductor memory device.

FIG. 4 is a schematic plan view showing a configuration of an upper memory chip.

FIG. 5 is a schematic plan view showing a configuration of a lower memory chip.

FIG. 6 is a schematic plan view showing a configuration of a peripheral circuit chip

FIG. 7 is a schematic cross-sectional view showing a structure of a part of a memory region.

FIG. 8 is a schematic bottom view showing a structure of a part of the memory region.

FIG. 9 is a schematic cross-sectional view showing a configuration of a part of the memory region.

FIG. 10 is a schematic cross-sectional view showing a structure of a part of a word line connection region.

FIG. 11 is a schematic cross-sectional view showing a structure of a part of the word line connection region.

FIG. 12 is a schematic plan view showing a semiconductor memory device according to a second embodiment.

FIG. 13 is a schematic plan view showing the semiconductor memory device according to the second embodiment.

FIG. 14 is a schematic cross-sectional view showing the semiconductor memory device according to the second embodiment.

FIG. 15 is a schematic plan view showing a semiconductor memory device according to a third embodiment.

FIG. 16 is a schematic plan view showing the semiconductor memory device according to the third embodiment.

FIG. 17 is a schematic plan view showing a semiconductor memory device according to a fourth embodiment.

FIG. 18 is a schematic cross-sectional view showing a structure of a part of a memory region according to the fourth embodiment.

FIG. 19 is a schematic bottom view showing a structure of a part of the memory region according to the fourth embodiment.

FIG. 20 is a schematic bottom view showing a structure of a part of the memory region according to the fourth embodiment.

FIG. 21 is a schematic plan view showing a semiconductor memory device according to a fifth embodiment.

FIG. 22 is a schematic bottom view showing the semiconductor memory device according to the fifth embodiment.

FIG. 23 is a schematic cross-sectional view showing a semiconductor memory device according to a sixth embodiment.

### DETAILED DESCRIPTION

Embodiments provide a semiconductor memory device capable of being highly integrated.

In general, according to one embodiment, a semiconductor memory device includes a first chip, a second chip, and a third chip. The first chip includes a plurality of first structures arranged in a first direction and each including a plurality of first memory cells, a first bit line provided on one side of the plurality of first structures in a second direction intersecting the first direction, extending in the first direction, and connected to the plurality of first structures, and a first bonding electrode provided on one side of the first bit line in the second direction and electrically connected to the first bit line. The second chip includes a plurality of second structures arranged in the first direction and each including a plurality of second memory cells, a second bit line provided on one side of the plurality of second structures in the second direction, extending in the first direction, and connected to the plurality of second structures, a first via contact electrode extending in the second direction within a range corresponding to the plurality of second structures in the first direction and electrically connected to the first bit line and the second bit line, a second bonding electrode provided on one side of the first via contact electrode in the second direction, electrically connected to the first via contact electrode, and bonded to the third chip, and a third bonding electrode provided on the other side of the first via contact electrode in the second direction, electrically connected to the first via contact electrode, and bonded to the first bonding electrode. The third chip includes a first transistor electrically connected to the first bit line and the second bit line. One of the plurality of first structures is provided at a position overlapping the first via contact electrode when viewed in the second direction and is able to store data.

Hereafter, a semiconductor memory device according to embodiments will be described in detail with reference to the drawings. It should be noted that the following embodiments are merely examples and are not intended to limit the scope of the present disclosure. The drawings are schematic, and for convenience in explanation, some components may be omitted. Portions common to a plurality of embodiments are given the same reference numerals, and descriptions thereof may be omitted.

In the present specification, the term “semiconductor memory device” may refer to a memory die, or may refer to a memory system including a controller die, such as a memory chip, a memory card, or a solid state drive (SSD). The term “semiconductor memory device” may also refer to a configuration including a host computer, such as a smartphone, a tablet terminal, or a personal computer.

In the present specification, when it is mentioned that a first configuration is “electrically connected” to a second configuration, the first configuration may be directly connected to the second configuration, or the first configuration may be connected to the second configuration via a wiring, a semiconductor member, a transistor, or the like. For example, when three transistors are connected in series, even when a second transistor is in an OFF state, a first transistor is “electrically connected” to a third transistor.

In the present specification, when it is mentioned that a first configuration is “connected between” a second configuration and a third configuration, it may mean that the first configuration, the second configuration, and the third configuration are connected in series and the second configuration is connected to the third configuration via the first configuration.

In the present specification, when it is mentioned that a circuit or the like “conducts” two wirings or the like, it may mean, for example, that the circuit or the like includes a transistor or the like provided in a current path between the two wirings and in an ON state.

In the present specification, a predetermined direction parallel to an upper surface of a substrate is referred to as an X direction, a direction parallel to the upper surface of the substrate and perpendicular to the X direction is referred to as a Y direction, and a direction perpendicular to the upper surface of the substrate is referred to as a Z direction.

In the present specification, a direction along a predetermined plane may be referred to as a first direction, a direction that intersects the first direction along the predetermined plane may be referred to as a second direction, and a direction that intersects the predetermined plane may be referred to as a third direction. Each of the first direction, the second direction, and the third direction may or may not correspond to any one of the X direction, the Y direction, and the Z direction.

In the present specification, expressions such as “upper” and “lower” are based on the substrate. For example, a direction moving away from the substrate in the Z direction is referred to as “upper”, and a direction moving toward the substrate in the Z direction is referred to as “lower”. When the term “lower surface” or “lower end” is used for a certain configuration, the term indicates a surface or an end of the certain configuration on a side facing the substrate, and when the term “upper surface” or “upper end” is used for a certain configuration, the term indicates a surface or an end of the certain configuration on a side opposite to the substrate. A surface that intersects the X direction or the Y direction is referred to as a side surface or the like.

In the present specification, when “width”, “length”, or “thickness” in a predetermined direction is mentioned in a configuration, a member, or the like, the term may indicate a width, a length, or a thickness in a cross-section observed by scanning electron microscopy (SEM), transmission electron microscopy (TEM), and the like.

### First Embodiment

### Circuit Configuration of Memory Die MD

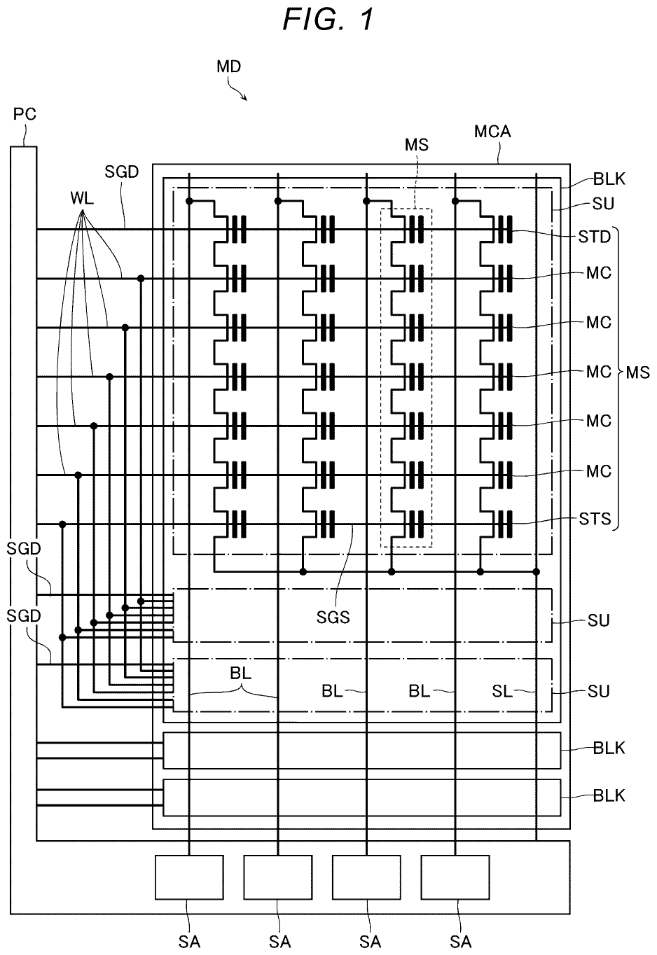

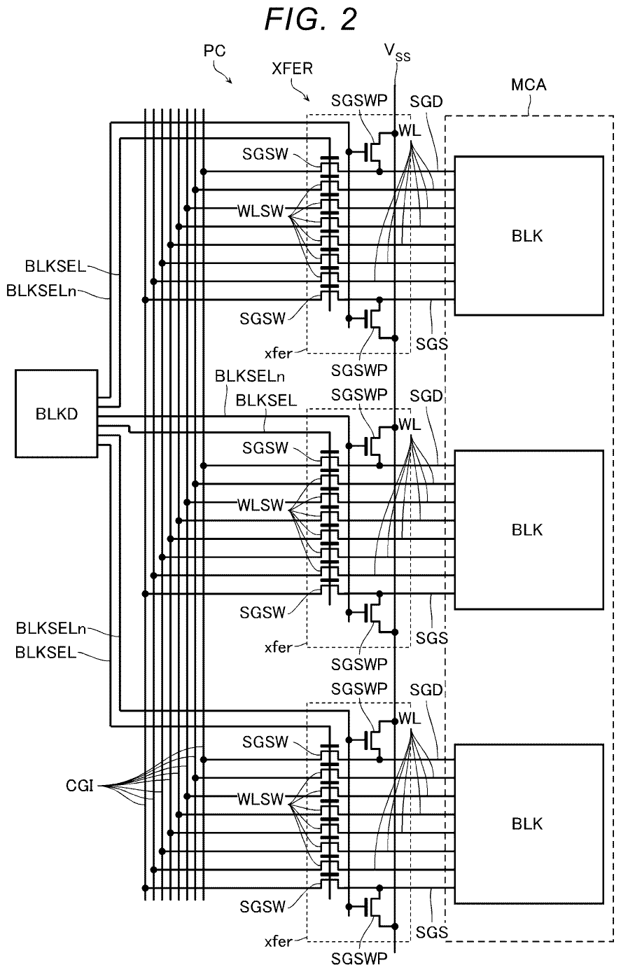

FIGS. 1 and 2 are schematic circuit diagrams showing a configuration of a semiconductor memory device according to a first embodiment. In the present embodiment, a memory die MD is illustrated as the semiconductor memory device.

As shown in FIG. 1, the memory die MD includes a memory cell array MCA and a peripheral circuit PC.

### Circuit Configuration of Memory Cell Array MCA

As shown in FIG. 1, the memory cell array MCA includes a plurality of memory blocks BLK. Each of the plurality of memory blocks BLK includes a plurality of string units SU. Each of the plurality of string units SU includes a plurality of memory strings MS. One end of each of the plurality of memory strings MS is connected to the peripheral circuit PC via a bit line BL. The other end of each of the plurality of memory strings MS is connected to the peripheral circuit PC via a common source line SL.

The memory string MS includes a drain-side select transistor STD, a plurality of memory cells MC (also referred to as memory transistors), and a source-side select transistor STS. The drain-side select transistor STD, the memory cells MC, and the source-side select transistor STS are connected in series between the bit line BL and the source line SL. Hereinafter, the drain-side select transistor STD and the source-side select transistor STS may be simply referred to as select transistors STD and STS.

The memory cell MC is a field effect transistor. The memory cell MC includes a semiconductor layer, a gate insulating film, and a gate electrode. The semiconductor layer functions as a channel region. The gate insulating film includes a charge storage film. A threshold voltage of the memory cell MC changes depending on the amount of charge in the charge storage film. The memory cell MC stores one bit or a plurality of bits of data. A word line WL is connected to each of the gate electrodes of the plurality of memory cells MC corresponding to one memory string MS. The word lines WL are connected in common to all memory strings MS in one memory block BLK.

The select transistors (STD and STS) are field effect transistors. Each of the select transistors (STD and STS) includes a semiconductor layer, a gate insulating film, and a gate electrode. The semiconductor layer functions as a channel region. The gate insulating film may include a charge storage film. A drain-side select gate line SGD is connected to the gate electrode of the drain-side select transistor STD, and a source-side select gate line SGS is connected to the gate electrode of the source-side select transistor STS. One drain-side select gate line SGD is connected in common to all memory strings MS in one string unit SU. One source-side select gate line SGS is connected in common to all memory strings MS in one memory block BLK.

### Circuit Configuration of Peripheral Circuit PC

The peripheral circuit PC includes a plurality of sense amplifier circuits SA each connected to a plurality of bit lines BL. Each of the plurality of sense amplifier circuits SA includes a sense node electrically connected to the bit line BL, a sense transistor including a gate electrode electrically connected to the sense node and a grounded source electrode, a data node electrically connected to a drain electrode of the sense transistor, a latch circuit connected to the data node, and a voltage supply circuit capable of supplying different voltages to the bit line BL depending on data stored in the latch circuit.

As shown in FIG. 2, the peripheral circuit PC further includes a voltage transfer circuit XFER and a block decoder BLKD.

The voltage transfer circuit XFER includes a plurality of voltage transfer units xfer respectively provided for a plurality of memory blocks BLK in the memory cell array MCA. The voltage transfer unit xfer includes a plurality of word line switches WLSW and a plurality of select gate line switches SGSW and SGSWP. The plurality of word line switches WLSW correspond to the plurality of word lines WL in the memory block BLK. The plurality of select gate line switches SGSW and SGSWP correspond to the drain-side select gate line SGD and the source-side select gate line SGS in the memory block BLK.

The word line switch WLSW is, for example, a field effect NMOS transistor. A drain electrode of the word line switch WLSW is connected to the word line WL. A source electrode of the word line switch WLSW is electrically connected to a voltage generation circuit (not shown) via a voltage supply line CGI. A gate electrode of the word line switch WLSW is connected to a block select line BLKSEL.

The select gate line switch SGSW is, for example, a field effect NMOS transistor. A drain electrode of the select gate line switch SGSW is connected to the drain-side select gate line SGD and the source-side select gate line SGS. A source electrode of the select gate line switch SGSW is electrically connected to the voltage generation circuit (not shown) via the voltage supply line CGI. A gate electrode of the select gate line switch SGSW is connected to the block select line BLKSEL.

The select gate line switch SGSWP is, for example, a field effect NMOS transistor. A drain electrode of the select gate line switch SGSWP is connected to the drain-side select gate line SGD and the source-side select gate line SGS. A ground voltage is supplied to a source electrode of the select gate line switch SGSWP. A gate electrode of the select gate line switch SGSWP is connected to a block select line BLKSELn.

Block select lines BLKSEL and BLKSELn are provided for each of the voltage transfer units xfer. The block select line BLKSEL is connected to all word line switches WLSW and select gate line switches SGSW in the voltage transfer unit xfer.

The block decoder BLKD decodes a block address, supplies an H state voltage to one block select line BLKSEL corresponding to the block address, and supplies an L state voltage to one block select line BLKSELn corresponding to the one block select line BLKSEL. The block decoder BLKD supplies the L state voltage to the rest of block select lines BLKSEL, and supplies the H state voltage to a plurality of block select lines BLKSELn corresponding to the rest of block select lines BLKSEL.

### Structure of Memory Die MD

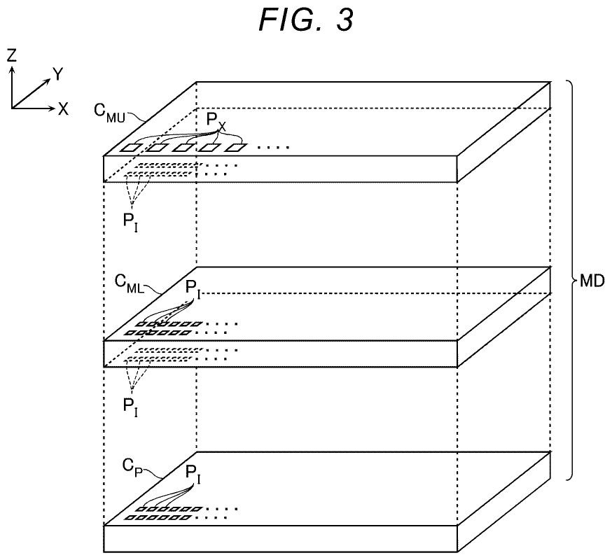

FIG. 3 is a schematic exploded perspective view showing a configuration example of the semiconductor memory device according to the first embodiment. As shown in FIG. 3, the memory die MD includes a chip C_{MU} including a part of the memory cell array MCA, a chip C_{ML} including the other part of the memory cell array MCA, and a chip C_{P} including the peripheral circuit PC.

A plurality of external pad electrodes P_{X} capable of connecting to a bonding wire (not shown) are provided on an upper surface of the chip C_{MU}. A plurality of bonding electrodes P_{I} are provided on a lower surface of the chip C_{MU}. A plurality of bonding electrodes P_{I} are provided on upper and lower surfaces of the chip C_{ML}. A plurality of bonding electrodes P_{I} are provided on an upper surface of the chip C_{P}. Hereafter, for the chips C_{MU} and C_{ML}, a surface facing the chip C_{P} is referred to as a front surface, and a surface opposite to the chip C_{P} is referred to as a back surface. For the chip C_{P}, a surface facing the chips C_{MU} and C_{ML} is referred to as a front surface, and a surface opposite to the chips C_{MU} and C_{ML} is referred to as a back surface. In the illustrated example, the front surfaces of the chips C_{MU} and C_{ML} are provided below the back surfaces of the chips C_{MU} and C_{ML}, and the front surface of the chip C_{P} is provided above the back surface of the chip C_{P}.

The plurality of bonding electrodes P_{I} provided on the lower surface of the chip C_{MU} are each bonded to the plurality of bonding electrodes P_{I} provided on the upper surface of the chip C_{ML}. The plurality of bonding electrodes P_{I} provided on the lower surface of the chip C_{ML} are each bonded to the plurality of bonding electrodes P_{I} provided on the upper surface of the chip C_{P}.

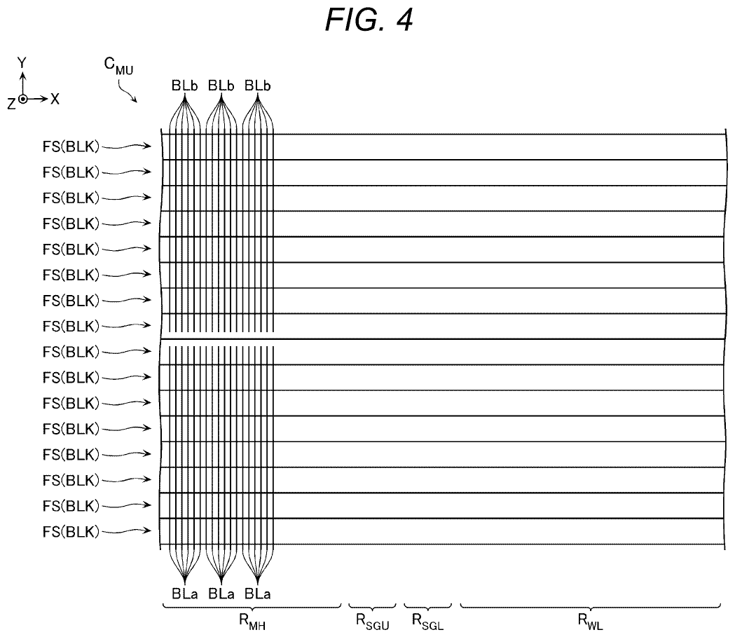

FIG. 4 is a schematic plan view showing a configuration of the chip C_{MU}. As shown in FIG. 4, the chip C_{MU} includes a plurality of finger structures FS arranged in the Y direction. In the present embodiment, one finger structure FS functions as one memory block BLK.

The chip C_{MU} is provided with a memory region R_{MH}, select gate line connection regions R_{SGU} and R_{SGL}, and a word line connection region R_{WL} arranged in the X direction.

In the memory region R_{MH}, a configuration corresponding to a plurality of memory strings MS (see FIG. 1) and a plurality of bit lines BL are disposed. Among the plurality of finger structures FS in the chip C_{MU}, finger structures FS provided on one side in the Y direction of a center position in the Y direction are connected to a plurality of bit lines BLa. Among the plurality of finger structures FS in the chip C_{MU}, finger structures FS provided on the other side in the Y direction of the center position in the Y direction are connected to a plurality of bit lines BLb.

In the select gate line connection region R_{SGU}, configurations for electrically connecting the drain-side select gate lines SGD (see FIG. 1) with the select gate line switches SGSW and SGSWP (see FIG. 2) in the chip C_{MU} are disposed. In the word line connection region R_{WL}, configurations for electrically connecting the word lines WL (see FIG. 1) with the word line switch WLSW (see FIG. 2) are disposed.

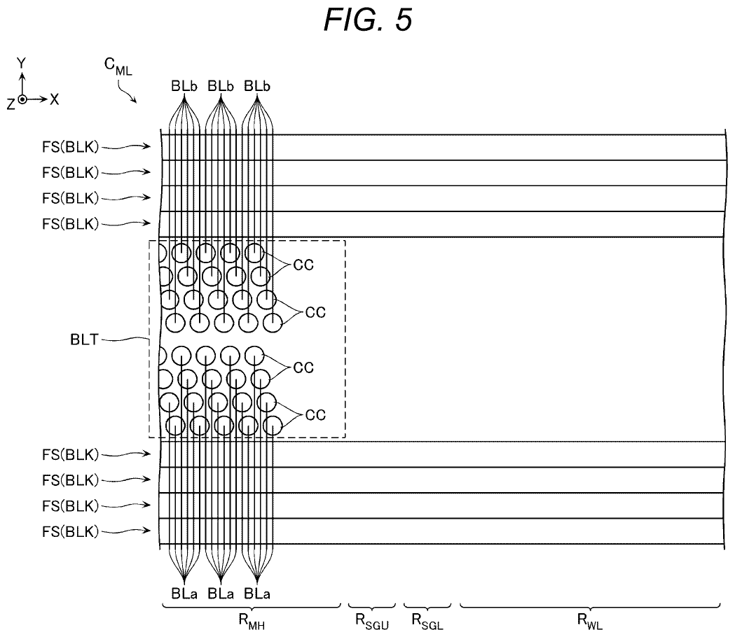

FIG. 5 is a schematic plan view showing a configuration of the chip C_{ML}. As shown in FIG. 5, the chip C_{ML} includes a plurality of finger structures FS arranged in the Y direction. Configurations of the finger structures FS in the chip C_{ML} are the same as the configurations of the finger structures FS in the chip C_{MU}. However, in the finger structures FS in the chip C_{ML}, configurations for electrically connecting the drain-side select gate lines SGD (see FIG. 1) with the select gate line switches SGSW and SGSWP (see FIG. 2) in the chip C_{ML} are disposed in the select gate line connection region R_{SGL}.

In the vicinity of the center position in the Y direction in the chip C_{ML}, a bit line tap BLT is provided instead of the finger structures FS. In the bit line tap BLT, configurations for electrically connecting the bit lines BLa and BLb in the chip C_{MU} with the bit lines BLa and BLb in the chip C_{ML} are disposed. The bit line tap BLT is provided in the memory region R_{MH}.

In the present embodiment, the finger structures FS are provided at positions overlapping the bit line tap BLT in the chip C_{MU} when viewed in the Z direction. Therefore, in the present embodiment, the amount of data capable of storing in the chip C_{MU} is greater than the amount of data capable of storing in the chip C_{ML}.

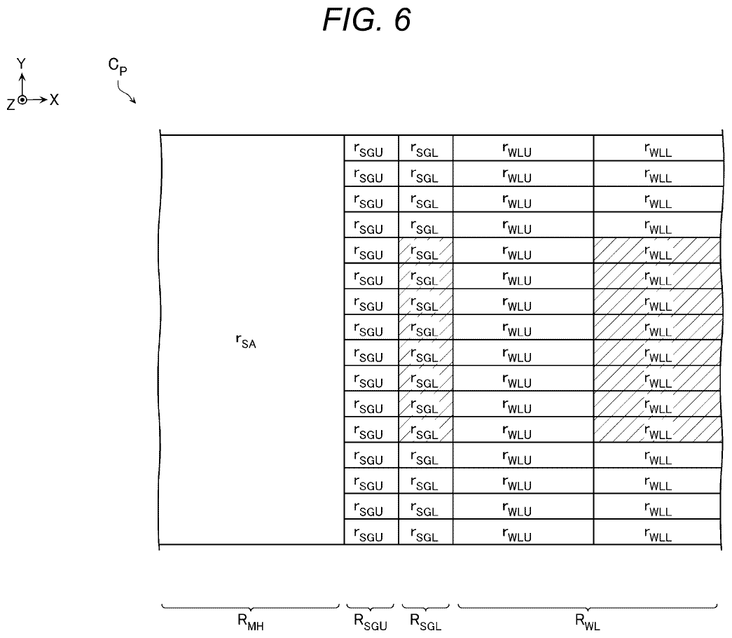

FIG. 6 is a schematic plan view showing a configuration of the chip C_{P}.

A sense amplifier region r_{SA} is provided in the memory region R_{MH} of the chip C_{P}. In the sense amplifier region r_{SA}, the plurality of sense amplifier circuits SA described above with reference to FIG. 1 are disposed.

Select gate line switch regions r_{SGU} are each provided at positions of the select gate line connection region R_{SGU} in the chip C_{P} overlapping the plurality of finger structures FS in the chips C_{MU} and C_{ML} when viewed in the Z direction. In the select gate line switch region r_{SGU}, the plurality of select gate line switches SGSW and SGSWP electrically connected to the drain-side select gate line SGD in the chip C_{MU} are disposed. The plurality of select gate line switches SGSW and SGSWP are connected to the finger structures FS in the chip C_{MU} provided at overlapping positions when viewed in the Z direction.

Select gate line switch regions r_{SGL} are each provided at positions of the select gate line connection region R_{SGL} in the chip C_{P} overlapping the plurality of finger structures FS in the chips C_{MU} and C_{ML} when viewed in the Z direction. In the select gate line switch region r_{SGL}, the plurality of select gate line switches SGSW and SGSWP electrically connected to the drain-side select gate lines SGD in the chip C_{ML} are disposed.

The plurality of select gate line switches SGSW and SGSWP are connected to the finger structures FS in the chip C_{ML} provided at overlapping positions when viewed in the Z direction. However, the plurality of select gate line switches SGSW and SGSWP in the select gate line connection region R_{SGL} provided at positions in the Y direction corresponding to the bit line tap BLT (see FIG. 5) are not connected anywhere and serve as dummy structures. In such regions, the select gate line switches SGSW and SGSWP may be omitted or other configurations may be provided.

A word line switch region r_{WLU} and a word line switch region r_{WLL} are provided at each of positions of the word line connection region R_{WL} in the chip C_{P} overlapping the plurality of finger structures FS in the chips C_{MU} and C_{ML} when viewed in the Z direction.

In the word line switch region r_{WLU}, the plurality of word line switches WLSW electrically connected to the word lines WL in the chip C_{MU} are disposed. The plurality of word line switches WLSW are connected to the finger structures FS in the chip C_{MU} provided at overlapping positions when viewed in the Z direction.

In the word line switch region r_{WLL}, the plurality of word line switches WLSW electrically connected to the word lines WL in the chip C_{ML} are disposed. The plurality of word line switches WLSW are connected to the finger structures FS in the chip C_{ML} provided at overlapping positions when viewed in the Z direction. However, the plurality of word line switches WLSW in the word line switch regions r_{WLL} provided at positions in the Y direction corresponding to the bit line tap BLT (see FIG. 5) are not connected anywhere and serve as dummy structures. In such regions, the word line switches WLSW may be omitted or other configurations may be provided.

### Structure of Memory Region R_{MH}

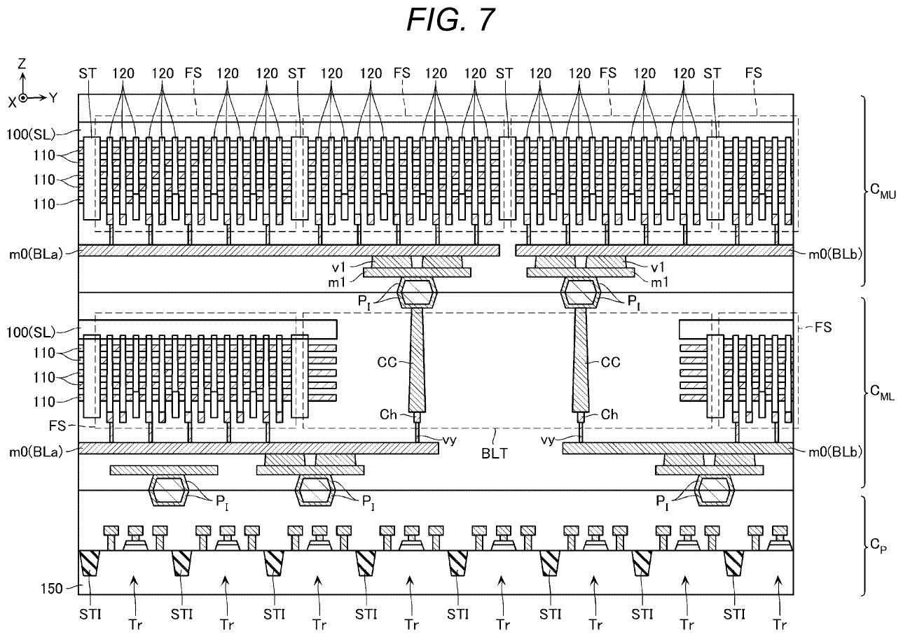

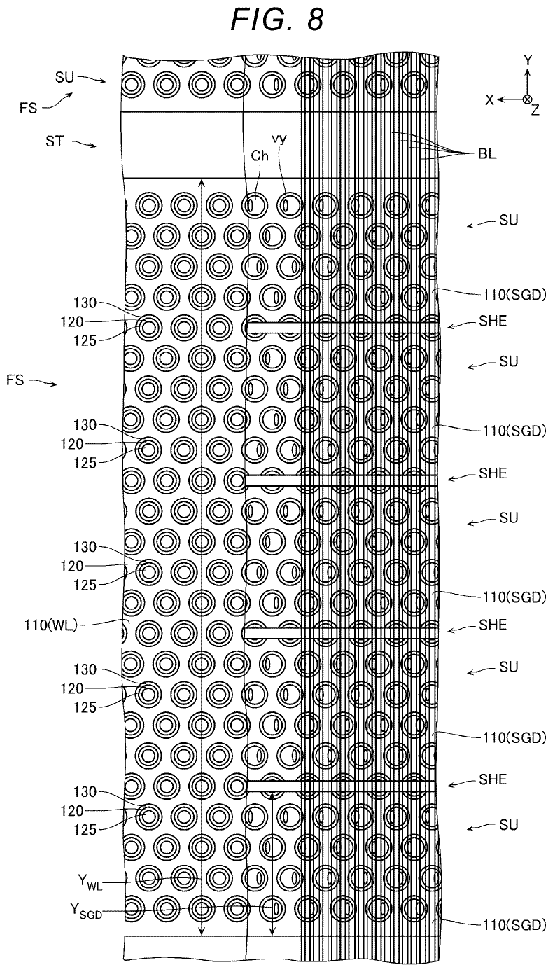

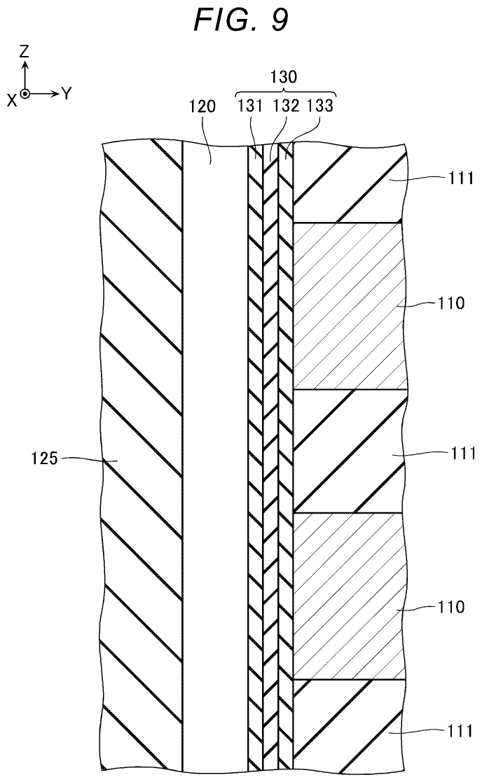

FIG. 7 is a schematic cross-sectional view showing a structure of a part of the memory region R_{MH}. In FIG. 7, a part of conductive layers 110 are omitted. FIG. 8 is a schematic bottom view showing a structure of a part of the memory region R_{MH}. A left region of FIG. 8 shows an XY cross-section at a height position corresponding to the word line WL. An insulating layer and the like are omitted from a right region of FIG. 8. The right region of FIG. 8 shows via contact electrodes Ch and vy and the bit line BL. Although not shown, the via contact electrodes Ch and vy and the bit line BL are also provided in the left region of FIG. 8. FIG. 9 is a schematic cross-sectional view showing a configuration of a part of the memory region R_{MH}. Although FIG. 9 shows a YZ cross-section, a structure same as that of FIG. 9 is observed when observing a cross-section other than the YZ cross-section along the central axis of a semiconductor pillar 120 (for example, an XZ cross-section).

As shown in FIG. 7, the chips C_{MU} and C_{ML} is provided with a plurality of finger structures FS and a plurality of inter-finger insulating layers ST alternately arranged in the Y direction, a conductive layer 100 provided above such a stacked body, and a plurality of wirings m0 and m1 provided under such a stacked body. The finger structure FS includes a plurality of conductive layers 110 arranged in the Z direction and a plurality of semiconductor pillars 120 extending in the Z direction. As shown in FIG. 9, a gate insulating film 130 is provided between each of the conductive layers 110 and each of the semiconductor pillars 120.

The conductive layer 110 has a substantially plate-like shape extending in the X-direction. The conductive layer 110 may include a stacked film of a barrier conductive film such as titanium nitride (TiN) and a metal film such as tungsten (W) or molybdenum (Mo). The conductive layer 110 may also include, for example, polycrystalline silicon including impurities such as phosphorus (P) or boron (B). Between the conductive layers 110 arranged in the Z direction, an interlayer insulating layer 111 such as silicon oxide (SiO₂) is provided.

The plurality of conductive layers 110 mainly function as the gate electrodes of the memory cells MC (see FIG. 1) and the word lines WL. The plurality of conductive layers 110 are electrically independent for each memory block BLK.

Although not shown in FIG. 7, one or a plurality of uppermost conductive layers 110 function as the gate electrodes of the source-side select transistors STS (see FIG. 1) and the source-side select gate lines SGS. The plurality of conductive layers 110 are electrically independent for each memory block BLK.

Although not shown in FIG. 7, one or a plurality of lowermost conductive layers 110 function as the gate electrodes of the drain-side select transistors STD (see FIG. 1) and the drain-side select gate lines SGD. For example, as shown in FIG. 8, a width Y_{SGD} of the plurality of conductive layers 110 in the Y direction is smaller than a width Y_{WL} of the conductive layer 110 in the Y direction functioning as the word line WL. Between two conductive layers 110 adjacent to each other in the Y direction, an inter-string unit insulating layer SHE such as silicon oxide (SiO₂) is provided.

The semiconductor pillars 120 are arranged in a predetermined pattern in the X direction and the Y direction, for example, as shown in FIG. 8. Each semiconductor pillar 120 functions as a channel region for the plurality of memory cells MC and the select transistors STD and STS in one memory string MS (see FIG. 1). The semiconductor pillar 120 includes, for example, polycrystalline silicon (Si). The semiconductor pillar 120 has a substantially cylindrical shape, and an insulating layer 125 such as silicon oxide is provided in a center portion of the semiconductor pillar 120. An outer circumferential surface of each semiconductor pillar 120 is surrounded by the plurality of conductive layers 110 and faces the plurality of conductive layers 110.

An impurity region (not shown) is provided at an upper end of the semiconductor pillar 120. The impurity region is connected to the above-described conductive layer 100. The impurity region includes N-type impurities, for example, such as phosphorus (P).

An impurity region (not shown) is provided at a lower end of the semiconductor pillar 120. The impurity region is connected to the bit line BL via the via contact electrode Ch and the via contact electrode vy. The impurity region includes N-type impurities, for example, such as phosphorus (P).

As shown in FIG. 9, the gate insulating film 130 has a substantially cylindrical shape covering the outer circumferential surface of the semiconductor pillar 120. The gate insulating film 130 includes a tunnel insulating film 131, a charge storage film 132, and a block insulating film 133 stacked between the semiconductor pillar 120 and the conductive layer 110. The tunnel insulating film 131 and the block insulating film 133 include, for example, silicon oxide (SiO₂), silicon oxynitride (SiON), and the like. The charge storage film 132 includes, for example, a film capable of storing charge such as silicon nitride (SiN). The tunnel insulating film 131, the charge storage film 132, and the block insulating film 133 have a substantially cylindrical shape and extend in the Z direction along the outer circumferential surface of the semiconductor pillar 120 except for a contact portion between the semiconductor pillar 120 and the conductive layer 100.

FIG. 9 shows an example in which the gate insulating film 130 includes the charge storage film 132 such as silicon nitride or the like. Alternatively, the gate insulating film 130 may include a floating gate such as polycrystalline silicon including N-type or P-type impurities.

As shown in FIG. 7, the bit line tap BLT is provided in the chip C_{ML}. The bit line tap BLT includes a plurality of via contact electrodes CC respectively provided for the plurality of bit lines BLa and BLb. The via contact electrode CC extends in the Z direction by a distance corresponding to a distance from an upper end to a lower end of the plurality of conductive layers 110 in the chip C_{ML} in the Z direction. The via contact electrode CC in the bit line tap BLT electrically connects the bit lines BLa and BLb in the chip C_{ML} with the bit lines BLa and BLb in the chip C_{MU}. A lower end of the via contact electrode CC in the bit line tap BLT is connected to the bit lines BLa and BLb via the via contact electrodes Ch and vy in the chip C_{ML}. An upper end of the via contact electrode CC in the bit line tap BLT is connected to the bit lines BLa and BLb via the bonding electrode P_{I}, and the wiring m1 and a via contact electrode v1 in the chip C_{MU}.

Ends of the bit lines BLa and BLb in the chip C_{ML} are provided at positions overlapping the bit line tap BLT when viewed in the Z direction. Ends of the bit lines BLa and BLb in the chip C_{MU} are provided at positions overlapping predetermined inter-finger insulating layers ST when viewed in the Z direction, in which the predetermined inter-finger insulating layers ST are provided at positions overlapping the bit line tap BLT when viewed in the Z direction.

The chips C_{MU} and C_{ML} include a plurality of wirings m0 provided below the plurality of finger structures FS, and a plurality of wirings m1 provided below the plurality of wirings m0.

The plurality of wirings m0 may include, for example, a stacked film of a barrier conductive film such as titanium nitride (TiN) and a metal film such as copper (Cu). The plurality of wirings m0 are mainly arranged in the X direction and extend in the Y direction. Among the plurality of wirings m0, the wirings m0 provided in the memory region R_{MH} function as the bit lines BL. The wirings m0 are connected to the semiconductor pillars 120 and the like via the via contact electrodes vy and Ch.

The plurality of wirings m1 may include, for example, a stacked film of a barrier conductive film such as titanium nitride (TiN) and a metal film such as tungsten (W). The plurality of wirings m1 are mainly arranged in the Y direction and extend in the X direction. The wiring m1 is connected to the wiring m0 via the via contact electrode v1. The bonding electrode P_{I} is connected to the lower surface of the wiring m1.

When a metal film such as copper (Cu) is used for the bonding electrode P_{I}, metal films bonded between two bonded electrodes P_{I} are integrated such that it is difficult identify a boundary therebetween. However, a bonded structure may be checked by shape distortion due to a positional misalignment in bonding or positional misalignment of a barrier conductive film (a discontinuous portion on a side surface). When the bonding electrodes P_{I} are formed by a damascene method, each side surface has a tapered shape. Accordingly, in a cross-sectional shape in the Z direction at a portion at which two bonding electrodes P_{I} are bonded, a sidewall does not have a straight shape, and has a non-rectangular shape. When two bonding electrodes P_{I} are bonded, a structure is formed in which a bottom surface, a side surface and an upper surface of each Cu contained in the two bonding electrodes P_{I} are covered with barrier metal. In contrast, in a wiring layer using general Cu, an insulating layer that has a function of preventing oxidation of Cu (SiN or SiCN) is provided on an upper surface of Cu, and barrier metal is not provided. Therefore, even when positional misalignment does not occur in the bonding, identification from a general wiring layer is possible.

As shown in FIG. 7, for example, a semiconductor substrate 150 is provided in the chip C_{P}. The semiconductor substrate 150 includes, for example, P-type silicon (Si) including P-type impurities such as boron (B). Although not shown, a surface of the semiconductor substrate 150 is provided with, for example, an N-type well region including N-type impurities such as phosphorus (P), a P-type well region including P-type impurities such as boron (B), and a semiconductor substrate region in which an N-type well region and a P-type well region are not provided.

The semiconductor substrate 150 is also provided with a plurality of transistors Tr and insulating regions STI such as silicon oxide (SiO₂) provided between the plurality of transistors Tr. The transistors Tr are each a field-effect transistor that uses the surface of the semiconductor substrate 150 as a channel region, a source region, and a drain region, and make up the peripheral circuit PC with a plurality of wirings (not shown). The transistor Tr disposed in the memory region R_{MH} functions as a part of the sense amplifier circuit SA.

### Structure of Word Line Connection Region R_{WL}

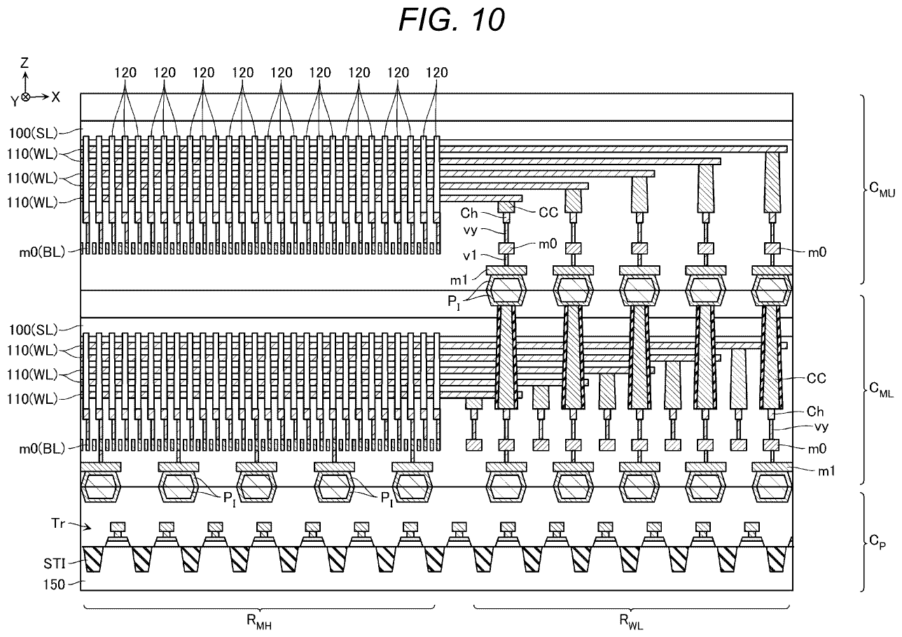

FIG. 10 is a schematic cross-sectional view showing a structure of a part of the word line connection region R_{WL}. FIG. 10 shows an XZ cross-section at a position in the Y direction corresponding to the finger structure FS in the chips C_{MU} and C_{ML}. In FIG. 10, configurations in the select gate line connection regions R_{SGU} and R_{SGL} and a part of the conductive layers 110 are omitted.

In the word line connection region R_{WL} of the chip C_{ML}, a plurality of via contact electrodes CC are provided. A first part of the via contact electrodes CC are respectively provided for the conductive layers 110 in the chip C_{ML} and upper ends thereof are connected to the conductive layers 110. A second part of the via contact electrodes CC are respectively provided for the conductive layers 110 in the chip C_{MU}. The second part of the via contact electrodes CC extend in the Z direction penetrating the conductive layers 110 in the chip C_{ML} and upper ends thereof are connected to the bonding electrodes P_{I}. An insulating layer such as silicon oxide (SiO₂) is formed on outer circumferential surfaces of the via contact electrodes CC. Lower ends of all via contact electrodes CC are connected to the bonding electrodes P_{I} via the via contact electrodes Ch, vy, and v1 and the wirings m0 and m1.

A plurality of via contact electrodes CC are provided in the word line connection region R_{WL} of the chip C_{MU}. The via contact electrodes CC are respectively provided for the conductive layers 110 in the chip C_{MU} and upper ends thereof are connected to the conductive layers 110. Lower ends of the via contact electrodes CC are connected to the bonding electrodes P_{I} via the via contact electrodes Ch, vy, and v1 and the wirings m0 and m1.

A plurality of transistors Tr are provided in the word line connection region R_{WL} of the chip C_{P}. The plurality of transistors Tr function as the word line switches WLSW (see FIG. 2). Drain electrodes of a part of the transistors Tr are electrically connected to the conductive layers 110 in the chip C_{ML} via the via contact electrodes CC in the chip C_{ML}. Drain electrodes of the rest of the transistors Tr are electrically connected to the conductive layers 110 in the chip C_{MU} via the via contact electrodes CC in the chips C_{ML} and C_{MU}.

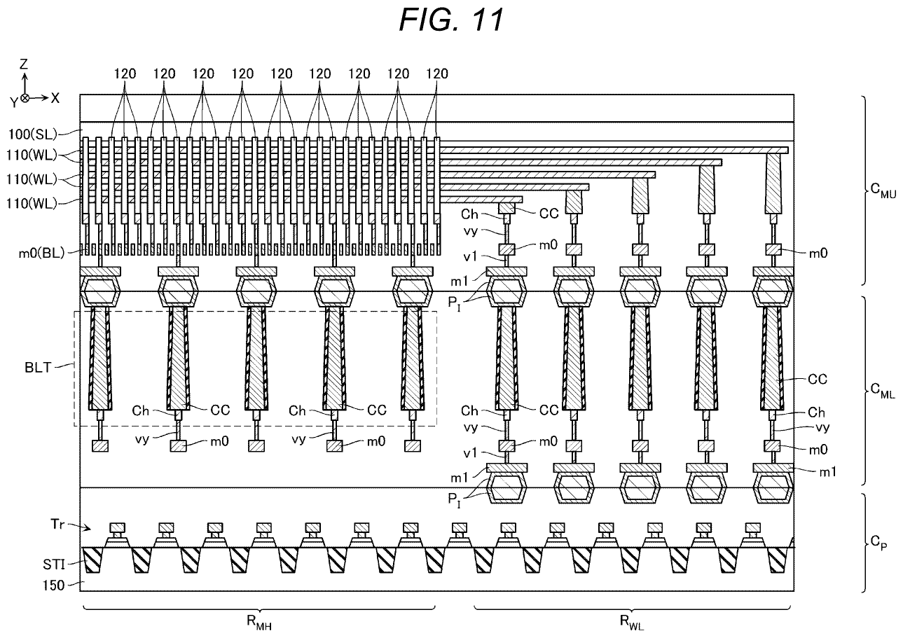

FIG. 11 is a schematic cross-sectional view showing a part of a structure of the word line connection region R_{WL}. FIG. 11 shows an XZ cross-section at a position in the Y direction corresponding to the finger structure FS in the chip C_{MU} and the bit line tap BLT in the chip C_{ML}. In FIG. 11, configurations in the select gate line connection regions R_{SGU} and R_{SGL} and a part of the conductive layers 110 are omitted.

The structure in the word line connection region R_{WL} at a position in the Y direction corresponding to the bit line tap BLT (see FIG. 11) is basically same as the structure in the word line connection region R_{WL} at a position in the Y direction corresponding to the finger structure FS in the chip C_{ML} (FIG. 10). However, at the position in the Y direction corresponding to the bit line tap BLT, the second part of the via contact electrodes CC corresponding to the conductive layers 110 in the chip C_{ML} and the via contact electrodes Ch, vy, and v1 and the wirings m0 and m1 corresponding to the second part of the via contact electrodes CC are not provided.

### Effects

As described above with reference to FIG. 3, the semiconductor memory device according to the present embodiment includes the chip C_{MU} including a part of the memory cell array MCA, the chip C_{ML} including the other part of the memory cell array MCA, and the chip C_{P} including the peripheral circuit PC.

In such a configuration, as described above with reference to FIG. 7 and the like, the bit line tap BLT for electrically connecting the bit lines BL in the chip C_{MU} to the bit lines BL in the chip C_{ML} is required. Therefore, the memory block BLK (the finger structure FS) cannot be provided in a part of the region of the chip C_{ML}. However, the memory block BLK (the finger structure FS) may be provided in a region of the chip C_{MU} corresponding to the bit line tap BLT.

Thus, in the present embodiment, the memory block BLK (the finger structure FS) is provided in a region of the chip C_{MU} overlapping the bit line tap BLT when viewed in the Z direction. According to such a configuration, because the region of the chip C_{MU} overlapping the bit line tap BLT when viewed in the Z direction is efficiently utilized, it is possible to achieve high integration of the semiconductor memory device.

### Second Embodiment

Next, a semiconductor memory device according to a second embodiment will be described. In the following description, the same portions as those in the first embodiment are denoted by the same reference numerals, and the description thereof will be omitted.

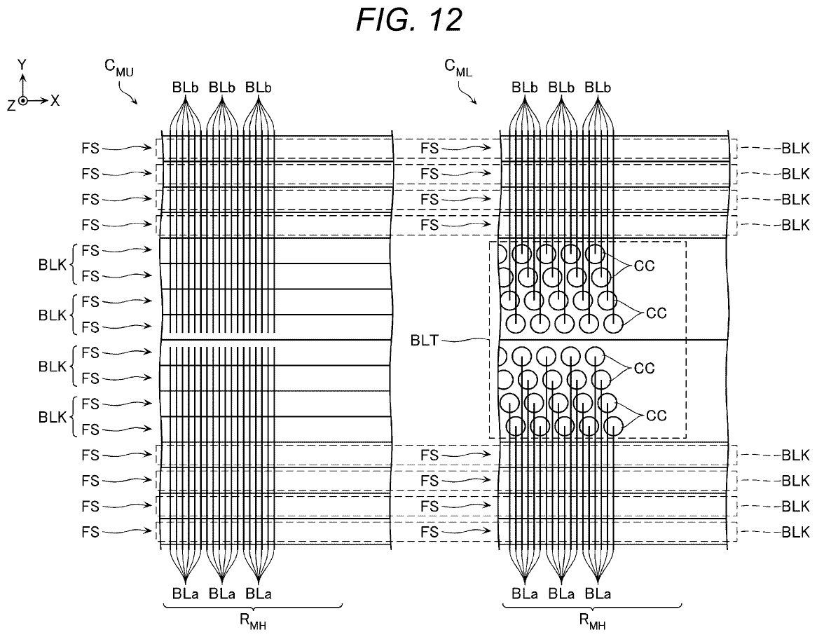

FIG. 12 is a schematic plan view showing the semiconductor memory device according to the second embodiment. FIG. 12 shows a part of the chip C_{MU} and a part of the chip C_{ML}.

Basically, the semiconductor memory device according to the second embodiment is configured similarly to the semiconductor memory device according to the first embodiment.

It should be noted that, in the first embodiment, one finger structure FS functions as one memory block BLK. Therefore, for example, as illustrated in FIG. 8, when one finger structure FS includes five string units SU, one memory block BLK includes five string units SU.

Meanwhile, in the second embodiment, as shown in FIG. 12, two finger structures FS function as one memory block BLK.

For example, among the finger structures FS in the chip C_{MU}, the finger structure FS provided at a position overlapping the finger structure FS in the chip C_{ML} when viewed in the Z direction functions as one memory block BLK with the overlapping finger structure FS in the chip C_{ML}. Among the finger structures FS in the chip C_{MU}, the finger structure FS provided at a position overlapping the bit line tap BLT functions as one memory block BLK with another finger structure FS adjacent in the Y direction.

In the second embodiment, the string unit SU in one finger structure FS and the string unit SU in another finger structure FS are handled as different string units SU. Therefore, for example, as illustrated in FIG. 8, when one finger structure FS includes five string units SU, one memory block BLK includes ten string units SU.

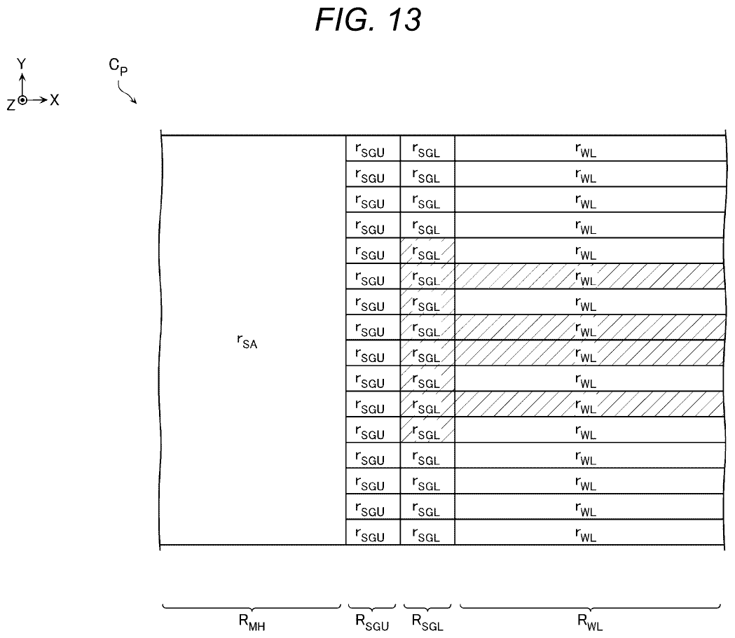

FIG. 13 is a schematic plan view showing the semiconductor memory device according to the second embodiment. FIG. 13 shows a part of the chip C_{P}.

Basically, the chip C_{P} according to the second embodiment is configured similarly to the chip C_{P} according to the first embodiment.

However, the word line switch region r_{WL} is provided at a position of the word line connection region R_{WL} in the chip C_{P} according to the second embodiment overlapping the plurality of finger structures FS in the chips C_{MU} and C_{ML} when viewed in the Z direction.

In the word line switch region r_{WL}, the plurality of word line switches WLSW electrically connected to the word lines WL in the chip C_{MU} and the word lines WL in the chip C_{ML} are disposed. That is, drain electrodes of the word line switches WLSW in the word line switch region r_{WL} are electrically connected in common to the word lines WL in the chip C_{MU} and the word lines WL in the chip C_{ML}. The plurality of word line switches WLSW are connected to the finger structures FS in the chips C_{MU} and C_{ML} provided at overlapping positions when viewed in the Z direction.

The plurality of word line switches WLSW in one half of the plurality of word line switch regions r_{WL} provided at positions in the Y direction corresponding to the bit line tap BLT are connected to two finger structures FS adjacent in the Y direction at positions overlapping the bit line tap BLT when viewed in the Z direction among the finger structures FS in the chip C_{MU}. Meanwhile, the plurality of word line switches WLSW in the other half of the plurality of word line switch regions r_{WL} provided at positions in the Y direction corresponding to the bit line tap BLT (see FIG. 5) are not connected anywhere and serve as dummy structures. In such regions, the word line switches WLSW may be omitted and other configurations may be provided.

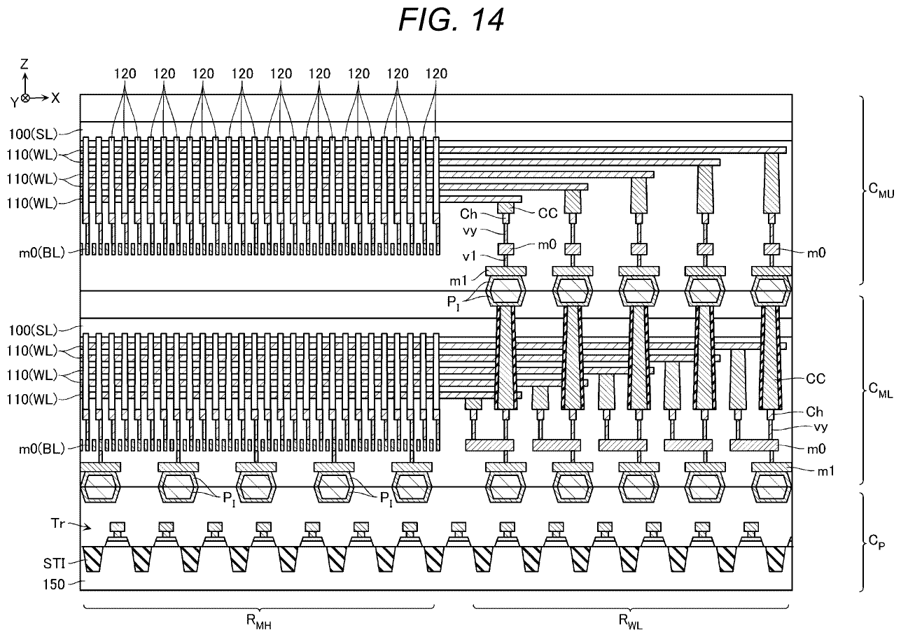

FIG. 14 is a schematic cross-sectional view showing the semiconductor memory device according to the second embodiment. FIG. 14 shows an XZ cross-section at a position in the Y direction corresponding to the finger structures FS in the chips C_{MU} and C_{ML}. In FIG. 14, configurations in the select gate line connection regions R_{SGU} and R_{SGL} and a part of the conductive layers 110 are omitted.

Basically, a structure in the word line connection region R_{WL} of the semiconductor memory device according to the second embodiment is similar to the structure in the word line connection region R_{WL} of the semiconductor memory device according to the first embodiment. However, as described above, in the second embodiment, the drain electrodes of the word line switches WLSW in the word line switch regions r_{WL} are electrically connected in common to the word lines WL in the chip C_{MU} and the word lines WL in the chip C_{ML}. In the example of FIG. 14, the via contact electrode CC connected to the conductive layer 110 in the chip C_{MU} and the via contact electrode CC connected to the conductive layer 110 in the chip C_{ML} are electrically connected via the wiring m0 in the chip C_{MU}.

With such a configuration, it is possible to reduce the number of word line switches WLSW up to half compared to the first embodiment. Accordingly, a circuit area in the chip C_{P} is reduced.

### Third Embodiment

Next, a semiconductor memory device according to a third embodiment will be described. In the following description, the same portions as those in the first embodiment or the second embodiment are denoted by the same reference numerals, and the description thereof will be omitted.

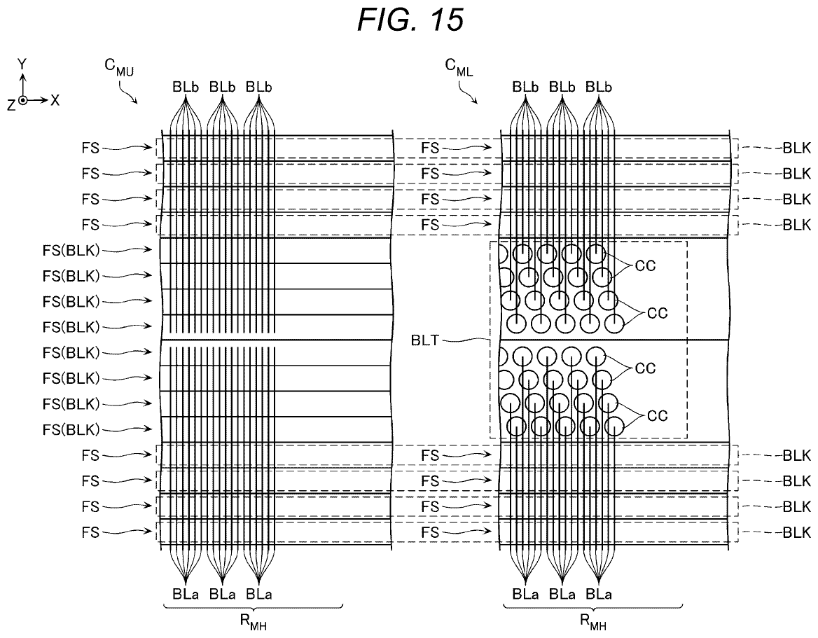

FIG. 15 is a schematic plan view showing the semiconductor memory device according to the third embodiment. FIG. 15 shows a part of the chip C_{MU} and a part of the chip C_{ML}.

Basically, the semiconductor memory device according to the third embodiment is configured similarly to the semiconductor memory device according to the second embodiment.

However, in the third embodiment, a part of the finger structures FS each function as one memory block BLK. Therefore, for example, as illustrated in FIG. 8, when one finger structure FS includes five string units SU, a part of memory blocks BLK include only five string units SU.

In detail, for example, among the finger structures FS in the chip C_{MU}, the finger structures FS provided at positions overlapping the bit line tap BLT each function as one memory block BLK.

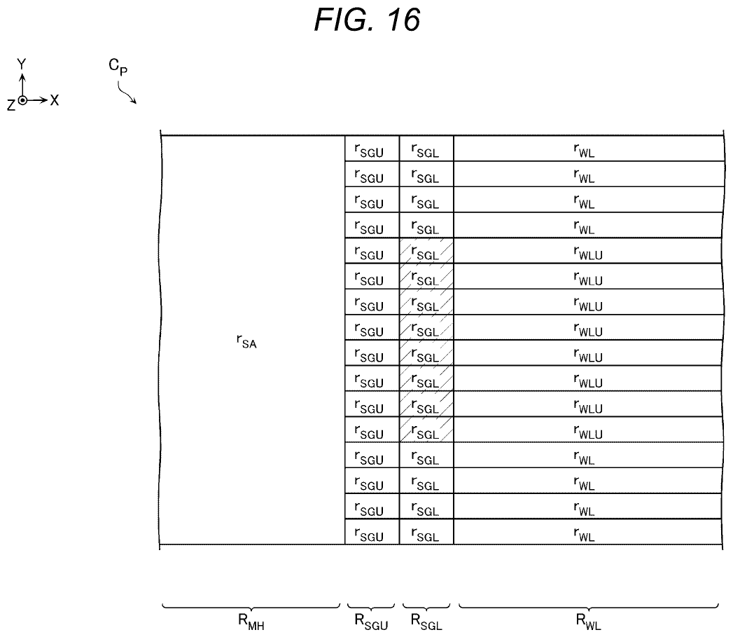

FIG. 16 is a schematic plan view showing the semiconductor memory device according to the third embodiment. FIG. 16 shows a part of the chip C_{P}.

Basically, the chip C_{P} according to the third embodiment is configured similarly to the chip C_{P} according to the second embodiment.

However, in the third embodiment, a word line switch region r_{WLU} instead of the word line switch region r_{WL} is provided within a range in the Y direction corresponding to the bit line tap BLT at positions overlapping the plurality of finger structures FS in the chip C_{MU} when viewed in the Z direction. As in the first embodiment, a plurality of word line switches WLSW in the word line switch regions r_{WLU} are connected to the finger structures FS in the chip C_{MU} provided at overlapping positions when viewed in the Z direction.

The word line switch WLSW in the word line switch region r_{WL} is electrically connected in common to the conductive layer 110 in the finger structure FS in the chip C_{MU} and the conductive layer 110 in the finger structure FS in the chip C_{ML}. Meanwhile, the word line switch WLSW in the word line switch region r_{WLU} is connected to only one conductive layer 110 in one finger structure FS in the chip C_{MU}. Therefore, it is possible to supply a voltage to the word lines WL in the memory blocks BLK corresponding to the word line switch regions r_{WLU} at a higher speed than to the word lines WL in the memory blocks BLK corresponding to the word line switch regions r_{WL}.

In the present embodiment, in two word line switch regions r_{WLU}, different signals are supplied to the block select line BLKSEL and the block select line BLKSELn. That is, the word line switches WLSW provided in the two word line switch regions r_{WL} are driven according to different block addresses.

However, even in the present embodiment, as in the example of FIG. 12, among the plurality of finger structures FS in the chip C_{MU}, the finger structure FS provided at a position overlapping the bit line tap BLT may be combined with another finger structure FS adjacent in the Y direction, thereby functioning as one memory block BLK. Here, for example, in two word line switch regions r_{WL} provided at positions overlapping the finger structures FS when viewed in the Z direction, a common signal may be supplied to the block select line BLKSEL and the block select line BLKSELn. That is, a plurality of word line switches WLSW provided in the two word line switch regions r_{WL} may be driven according to the same block address.

### Fourth Embodiment

Next, a semiconductor memory device according to a fourth embodiment will be described. In the following description, the same portions as those in the first embodiment to the third embodiment are denoted by the same reference numerals, and the description thereof will be omitted.

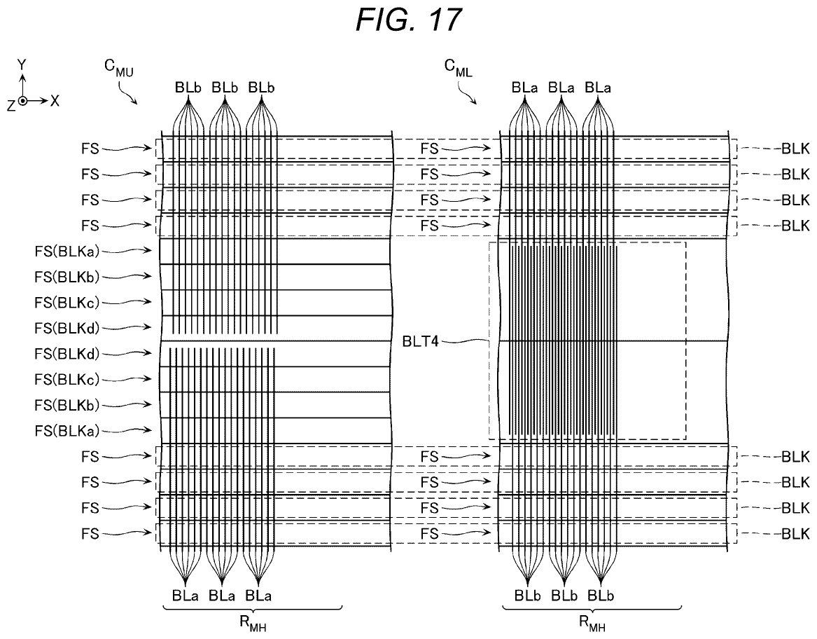

FIG. 17 is a schematic plan view showing the semiconductor memory device according to the fourth embodiment. FIG. 17 shows a part of the chip C_{MU} and a part of the chip C_{ML}.

Basically, the semiconductor memory device according to the fourth embodiment is configured similarly to the semiconductor memory device according to the second embodiment.

However, in the second embodiment, among the plurality of finger structures FS i the chip C_{MU}, the finger structures FS provided on one side in the Y direction of the center position in the Y direction are connected to the plurality of bit lines BLa, and the finger structures FS provided on the other side are connected to the plurality of bit lines BLb. Similarly, in the chip C_{ML}, the finger structures FS provided on one side in the Y direction of the center position in the Y direction are connected to the plurality of bit lines BLa, and the finger structures FS provided on the other side are connected to the plurality of bit lines BLb.

Meanwhile, in the fourth embodiment, among the plurality of finger structures FS in the chip C_{ML}, the finger structures FS provided on one side in the Y direction of the center position in the Y direction are connected to the plurality of bit lines BLb, and the finger structures FS provided on the other side are connected to the plurality of bit lines BLa. That is, positional relationships of the bit lines BLa and BLb are swapped between the chips C_{MU} and C_{ML}.

The semiconductor memory device according to the fourth embodiment includes a bit line tap BLT4 instead of the bit line tap BLT. Basically, the bit line tap BLT4 is configured similarly to the bit line tap BLT. However, the bit line tap BLT4 electrically connects the bit lines BLa provided on one side in the Y direction in the chip C_{MU} and the bit lines BLa provided on the other side in the Y direction in the chip C_{ML}. The bit line tap BLT4 also electrically connects the bit lines BLb provided on the other side in the Y direction in the chip C_{MU} and the bit lines BLb provided on one side in the Y direction in the chip C_{ML}.

In the fourth embodiment, among the plurality of finger structures FS provided at positions overlapping the bit line tap BLT4, one of the finger structures FS connected to the bit lines BLa (provided on one side in the Y direction) and one of the finger structures FS connected to the bit lines BLb (provided on the other side in the Y direction) function as one memory block BLK. In the example of FIG. 17, among the plurality of finger structures FS provided at positions overlapping the bit line tap BLT4, first to fourth finger structures FS counted from one side in the Y direction are each combined with first to fourth finger structures FS counted from the other side in the Y direction, thereby functioning as memory blocks BLKa, BLKb, BLKc, and BLKd.

With such a configuration, it is unnecessary to handle the string units SU in the chip C_{MU} and the string units SU in the chip C_{ML} as different string units SU, and it is possible to simultaneously select the string units SU provided at positions overlapping when viewed in the Z direction in the finger structures FS provided at positions overlapping when viewed in the Z direction. Therefore, it is possible to reduce the number of select gate line switches SGSW and SGSWP. Therefore, it is possible to further reduce a circuit area in the chip C_{P}.

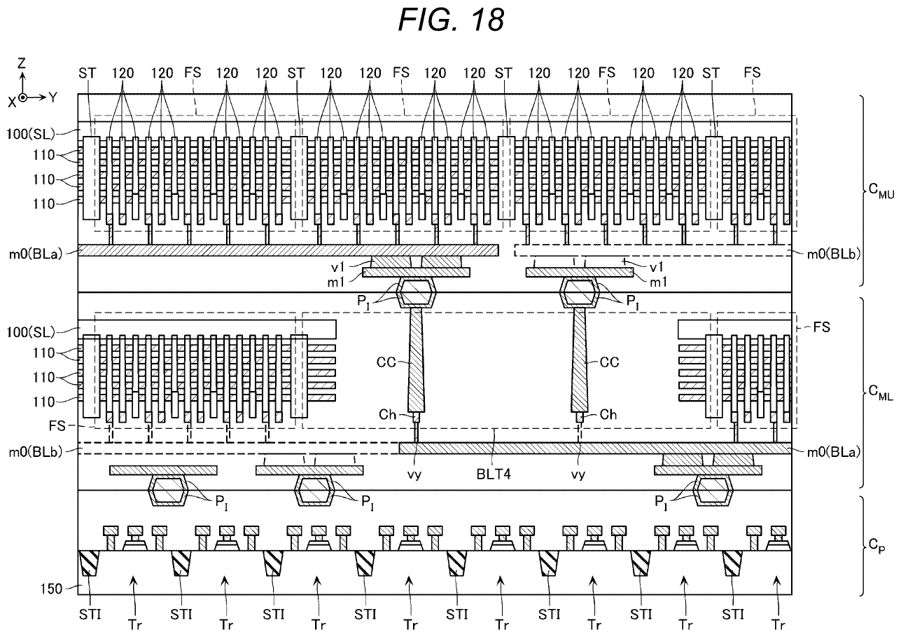

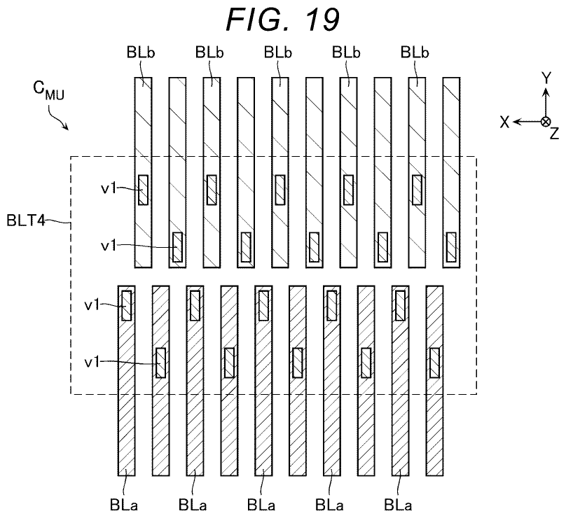

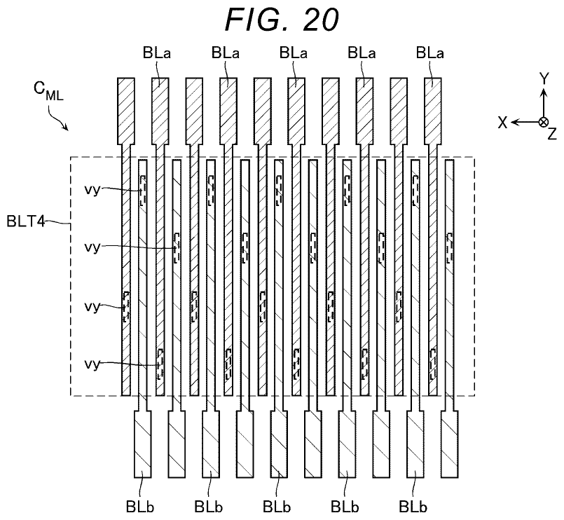

FIG. 18 is a schematic cross-sectional view showing a structure of a part of the memory region R_{MH}. In FIG. 18, a part of the conductive layers 110 are omitted. In the fourth embodiment, positions of the bit lines BLa and BLb are different in the X direction. In FIG. 18, a cross-section corresponding to the bit lines BLa is shown, and the bit lines BLb and a part of configurations connected thereto are shown by dotted lines. FIGS. 19 and 20 are schematic bottom views showing a structure of a part of the memory region R_{MH}. In FIG. 19, the bit lines BLa and BLb in the chip C_{MU} are shown. In FIG. 20, the bit lines BLa and BLb in the chip C_{ML} are shown.

As shown in FIG. 19, in the chip C_{MU} according to the fourth embodiment, the bit lines BLa are provided on one side of a predetermined position in the Y direction, and the bit lines BLb are provided on the other side of the predetermined position in the Y direction. The bit lines BLa and the bit lines BLb are disposed shifted from each other by half a pitch. In other words, a center position in the X direction of two bit lines BLa adjacent in the X direction coincides with a center position in the X direction of one bit line BLb. Similarly, a center position in the X direction of two bit lines BLb adjacent in the X direction coincides with a center position in the X direction of one bit line BLa. The bit lines BLa and BLb are connected to the via contact electrode v1 provided in a region overlapping the bit line tap BLT4 when viewed in the Z direction.

As shown in FIG. 20, also in the chip C_{ML} according to the fourth embodiment, the bit lines BLa and BLb are provided shifted from each other by half a pitch.

In the chip C_{ML}, the bit line BLa includes a portion provided on the other side of a predetermined position in the Y direction and a portion provided in the bit line tap BLT4. The bit line BLb includes a portion provided on one side of the predetermined position in the Y direction and a portion provided in the bit line tap BLT4. A width in the X direction of the portions of the bit lines BLa and BLb provided in the bit line tap BLT4 corresponds to about half of a width in the X direction of the other portions. The portion of the bit line BLa provided in the bit line tap BLT4 and the portion of the bit line BLb provided in the bit line tap BLT4 are disposed at positions overlapping each other when viewed in the X direction.

The bit lines BLa and BLb are connected to the via contact electrode vy provided in the bit line tap BLT4. The via contact electrode vy connected to the bit lines BLa is disposed on one side in the X direction of the via contact electrode vy connected to the bit lines BLb.

As shown in FIG. 18, the bit lines BLa in the chip C_{MU} are electrically connected to the bit lines BLa in the chip C_{ML} via the via contact electrode v1, the wiring m1, and the bonding electrode P_{I} in the chip C_{MU} and via the bonding electrode P_{I} and the via contact electrodes CC, Ch, and vy in the chip C_{ML}. The via contact electrodes CC are provided at positions overlapping the bit lines BLa in the chip C_{MU} (on one side in the Y direction of a predetermined position) when viewed in the Z direction.

Although not shown, the bit lines BLb in the chip C_{MU} are also electrically connected to the bit lines BLb in the chip C_{ML} via the via contact electrode v1, the wiring m1, and the bonding electrode P_{I} in the chip C_{MU} and via the bonding electrode P_{I} and the via contact electrodes CC, Ch, and vy in the chip C_{ML}. The via contact electrodes CC are provided at positions overlapping the bit lines BLb in the chip C_{MU} (on the other side in the Y direction of a predetermined position) when viewed in the Z direction.

### Fifth Embodiment

Next, a semiconductor memory device according to a fifth embodiment will be described. In the following description, the same portions as those in the first embodiment to the fourth embodiment are denoted by the same reference numerals, and the description thereof will be omitted.

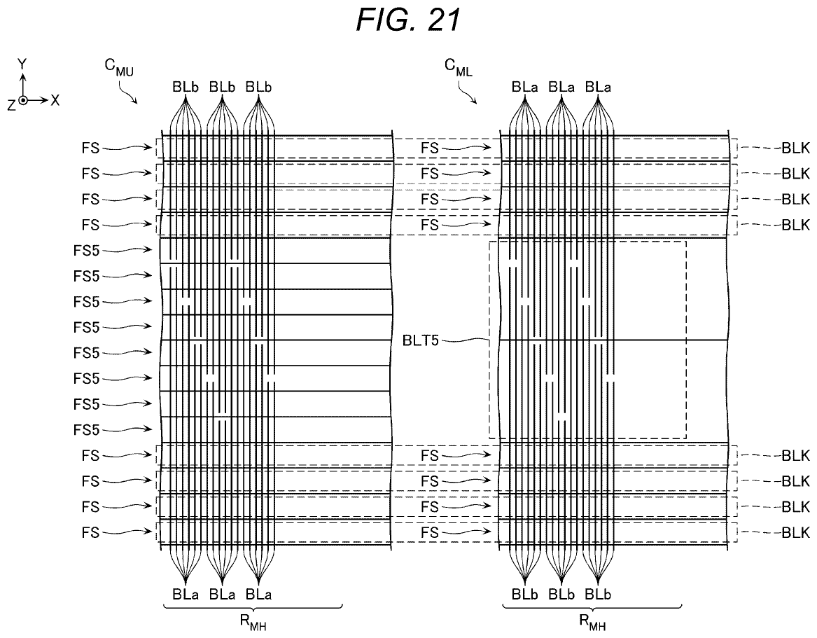

FIG. 21 is a schematic plan view showing the semiconductor memory device according to the fifth embodiment. FIG. 21 shows a part of the chip C_{MU} and a part of the chip C_{ML}.

Basically, the semiconductor memory device according to the fifth embodiment is configured similarly to the semiconductor memory device according to the fourth embodiment.

For example, as described above with reference to FIG. 17, in the fourth embodiment, among the plurality of finger structures FS in the chip C_{MU}, the finger structures FS provided on one side in the Y direction of the center position in the Y direction are connected to the plurality of bit lines BLa, and the finger structures FS provided on the other side are connected to the plurality of bit lines BLb. Among the plurality of finger structures FS in the chip C_{ML}, the finger structures FS provided on one side in the Y direction of the center position in the Y direction are connected to the plurality of bit lines BLb, and the finger structures FS provided on the other side are connected to the plurality of bit lines BLa. Such features are almost the same also in the semiconductor memory device according to the fifth embodiment.

However, as shown in FIG. 21, the semiconductor memory device according to the fifth embodiment includes a bit line tap BLT5 instead of the bit line tap BLT4. Finger structures FS5 are provided instead of the finger structures FS at positions overlapping the bit line tap BLT5 in the chip C_{MU} when viewed in the Z direction.

Basically, the finger structures FS5 are configured similarly to the finger structures FS. However, a part of the semiconductor pillars 120 in the finger structures FS5 are connected to the bit lines BLa, and another part of the semiconductor pillars 120 in the finger structures FS5 are connected to the bit lines BLb. The finger structures FS5 may include the semiconductor pillars 120 not connected to either the bit lines BLa or the bit lines BLb.

A structure in the finger structure FS5 may store, for example, a control parameter and the like of the semiconductor memory device.

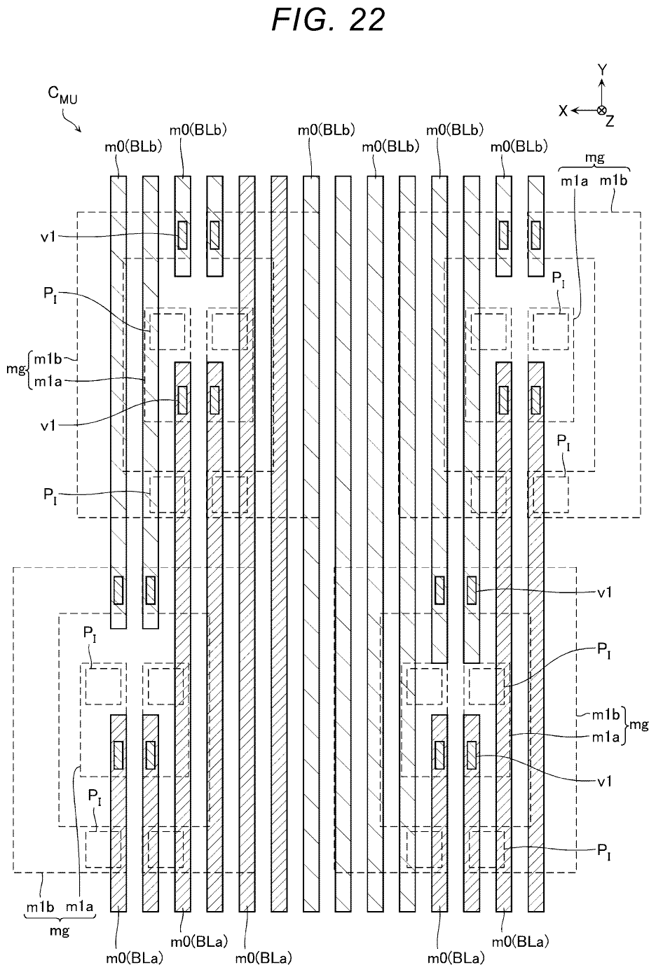

FIG. 22 is a schematic bottom view showing the semiconductor memory device according to the fifth embodiment. FIG. 22 shows a configuration of the chip C_{MU} in a region overlapping the bit line tap BLT5 when viewed in the Z direction.

As shown in FIG. 22, the chip C_{MU} according to the fifth embodiment includes a plurality of wirings m0 extending in the X direction and the Y direction. At a height position corresponding to the wiring m1 in the chip C_{MU}, a plurality of wiring groups mg arranged in a predetermined pattern in the X direction and the Y direction are provided. At a position overlapping the wiring group mg when viewed in the Z direction, a plurality of wirings m0 (two wirings m0 in the example of FIG. 22) are cut, and wirings m0 disposed on one side in the Y direction function as the bit lines BLa and wirings m0 disposed on the other side in the Y direction function as the bit lines BLb.

The plurality of wiring groups mg include a pair of wirings m1a and a pair of wirings m1b. The wirings m1a and m1b are four wirings among the plurality of wirings m1. Each of the pair of wirings m1a is connected to the bit lines BLa via the via contact electrode v1 and also connected to the bonding electrode P_{I}. Each of the pair of wirings m1b is connected to the bit lines BLb via the via contact electrode v1 and also connected to the bonding electrode P_{I}. Positions in the Y direction of the bonding electrodes P_{I} connected to the bit lines BLa are provided between positions in the Y direction of the via contact electrodes v1 connected to the bit lines BLb and positions in the Y direction of the bonding electrodes P_{I} connected to the bit lines BLb. The wirings m1b include portions overlapping the via contact electrodes v1 when viewed in the Z direction and extending in the X direction, portions overlapping the bonding electrodes P_{I} when viewed in the Z direction and extending in the X direction, and portions connected to ends in the X direction of the above portions, having different positions in the X direction from the wirings m1a, and extending in the Y direction.

### Sixth Embodiment

The semiconductor memory devices according to the first to fifth embodiments include two chips corresponding to the memory cell array MCA. However, the semiconductor memory devices according to the first to fifth embodiments may include three or more chips corresponding to the memory cell array MCA.

Hereinafter, an example in which the semiconductor memory device according to the first embodiment includes three chips corresponding to the memory cell array MCA will be described as a semiconductor memory device according to a sixth embodiment.

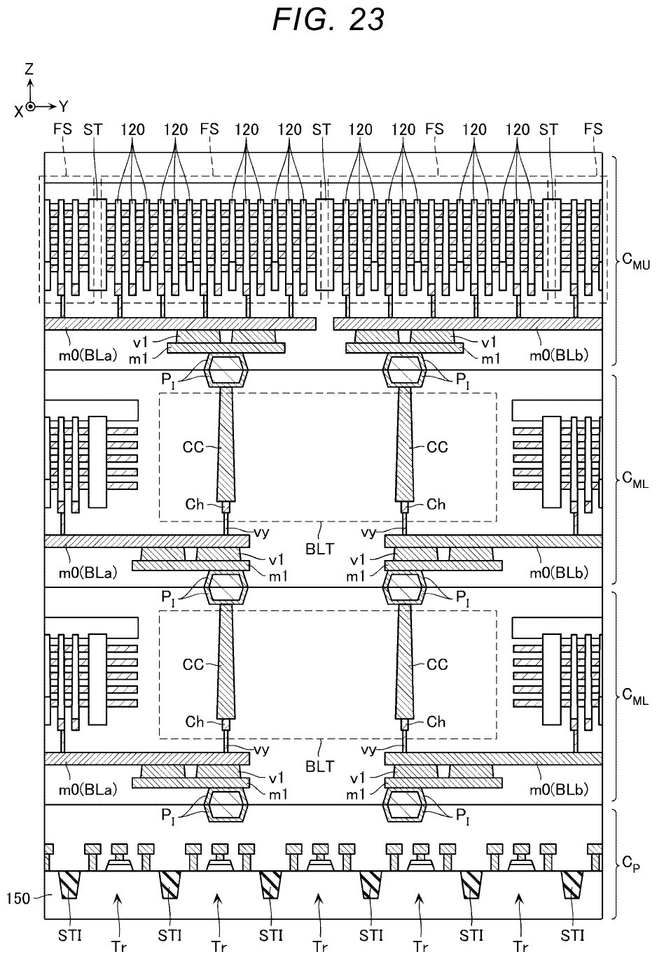

FIG. 23 is a schematic cross-sectional view showing the semiconductor memory device according to the sixth embodiment. In FIG. 23, a part of the conductive layers 110 are omitted.

Basically, the semiconductor memory device according to the sixth embodiment is configured similarly to the semiconductor memory device according to the first embodiment. However, in the semiconductor memory device according to the sixth embodiment, two chips C_{ML} are disposed between the chip C_{MU} and the chip C_{P}.

### Others

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first chip, a second chip, and a third chip, wherein
the first chip includes
a plurality of first structures arranged in a first direction and each including a plurality of first memory cells,
a first bit line provided on one side of the plurality of first structures in a second direction intersecting the first direction, extending in the first direction, and connected to the plurality of first structures, and
a first bonding electrode provided on one side of the first bit line in the second direction and electrically connected to the first bit line,
the second chip includes
a plurality of second structures arranged in the first direction and each including a plurality of second memory cells,
a second bit line provided on one side of the plurality of second structures in the second direction, extending in the first direction, and connected to the plurality of second structures,
a first via contact electrode extending in the second direction to overlap with the plurality of second structures when viewed in the first direction and electrically connected to the first bit line and the second bit line,
a second bonding electrode provided on one side of the first via contact electrode in the second direction, electrically connected to the first via contact electrode, and bonded to the third chip, and
a third bonding electrode provided on the other side of the first via contact electrode in the second direction, electrically connected to the first via contact electrode, and bonded to the first bonding electrode,
the third chip includes a first transistor electrically connected to the first bit line and the second bit line, and
one of the plurality of first structures is provided at a position overlapping the first via contact electrode when viewed in the second direction and is able to store data.

2. The semiconductor memory device according to claim 1, wherein each of the plurality of first structures and the plurality of second structures include
a plurality of conductive layers arranged in the second direction and extending in a third direction intersecting the first direction and the second direction,
a semiconductor pillar extending in the second direction and facing the plurality of conductive layers, and
a charge storage layer disposed between the plurality of conductive layers and the semiconductor pillar.

3. The semiconductor memory device according to claim 2, wherein the third chip further includes
a plurality of second transistors electrically connected to the plurality of conductive layers in one of the plurality of first structures, and
a plurality of third transistors electrically connected to the plurality of conductive layers in one of the plurality of second structures that is provided at a position overlapping the one of the plurality of first structures when viewed in the second direction, and
the plurality of second transistors and the plurality of third transistors are each controlled independently.

4. The semiconductor memory device according to claim 2, wherein the third chip further includes
a fourth transistor electrically connected to a first conductive layer among the plurality of conductive layers in one of the plurality of first structures and a second conductive layer among the plurality of conductive layers in one of the plurality of second structures.

5. The semiconductor memory device according to claim 4, wherein the first conductive layer and the second conductive layer are overlapping when viewed in the second direction.

6. The semiconductor memory device according to claim 4, wherein the third chip further includes
a fifth transistor connected to a third conductive layer among the plurality of conductive layers in one of the plurality of first structures that is provided at a position overlapping the first via contact electrode when viewed in the second direction, and a fourth conductive layer among the plurality of conductive layers in one of the plurality of first structures that is adjacent in the first direction to the one of the first structures including the third conductive layer.

7. The semiconductor memory device according to claim 4, wherein the third chip further includes
a sixth transistor connected to a third conductive layer among the plurality of conductive layers in one of the plurality of first structures that is provided at a position overlapping the first via contact electrode when viewed in the second direction, and
a seventh transistor connected to a fourth conductive layer among the plurality of conductive layers in one of the plurality of first structures that is adjacent in the first direction to the one of the first structures including the third conductive layer.

8. The semiconductor memory device according to claim 7, wherein the sixth transistor and the seventh transistor are driven according to different block addresses.

9. The semiconductor memory device according to claim 7, wherein the sixth transistor and the seventh transistor are driven according to the same block address.

10. The semiconductor memory device according to claim 1, wherein each of the plurality of second structures is provided at a position overlapping one of the plurality of first structures when viewed in the second direction.

11. The semiconductor memory device according to claim 1, wherein each of the plurality of second structures is provided at a position not overlapping any of the plurality of first structures when viewed in the second direction.

12. The semiconductor memory device according to claim 11, wherein
the first chip further includes
a plurality of third structures arranged in the first direction, each including a plurality of third memory cells, and provided at positions overlapping the plurality of second structures when viewed in the second direction,
a third bit line provided on one side of the plurality of third structures in the second direction, extending in the first direction, and connected to the plurality of third structures, and
a fourth bonding electrode provided on one side of the third bit line in the second direction and electrically connected to the third bit line,
the second chip further includes
a plurality of fourth structures arranged in the first direction, each including a plurality of fourth memory cells, and provided at positions overlapping the plurality of first structures when viewed in the second direction,
a fourth bit line provided on one side of the plurality of fourth structures in the second direction, extending in the first direction, and connected to the plurality of fourth structures,
a second via contact electrode extending in the second direction to overlap with the plurality of fourth structures when viewed in the first direction and electrically connected to the third bit line and the fourth bit line,
a fifth bonding electrode provided on one side of the second via contact electrode in the second direction, electrically connected to the second via contact electrode, and bonded to the third chip, and
a sixth bonding electrode provided on the other side of the second via contact electrode in the second direction, electrically connected to the second via contact electrode, and bonded to the fourth bonding electrode, and
the third chip further includes a fifth transistor electrically connected to the third bit line and the fourth bit line.

13. The semiconductor memory device according to claim 12, wherein
the second bit line and the fourth bit line include overlapping regions when viewed in a third direction intersecting the first direction and the second direction,
the first via contact electrode is provided between the plurality of second structures and the plurality of fourth structures in the first direction, and
the second via contact electrode is provided between the plurality of second structures and the first via contact electrode in the first direction.

14. The semiconductor memory device according to claim 12, wherein
the first bonding electrode is provided between the plurality of fourth structures and the plurality of third structures in the first direction, and
the fourth bonding electrode is provided between the plurality of first structures and the plurality of second structures in the first direction.

15. The semiconductor memory device according to claim 1, wherein
each of the first chip and the second chip include a plurality of memory blocks, and
the number of memory blocks in the first chip is greater than the number of memory blocks in the second chip.

16. The semiconductor memory device according to claim 15, wherein the plurality of first structures and the plurality of second structures each function as one of the plurality of memory blocks.

17. The semiconductor memory device according to claim 15, wherein a combination of one of the plurality of first structures and one of the plurality of second structures functions as one of the plurality of memory blocks.

18. The semiconductor memory device according to claim 17, wherein two of the plurality of first structures also function as one of the plurality of memory blocks.

19. A semiconductor memory device comprising:
a peripheral circuit chip formed on a substrate;
a first memory chip having a plurality of first memory cells, stacked on the peripheral circuit chip in a first direction;
a second memory chip having a plurality of second memory cells, stacked on the first memory chip in the first direction, wherein
the first memory chip has a first region including a plurality of contacts extending in the first direction for electrically connecting bit lines of the first and second memory chips to transistors of the peripheral circuit, and
the second memory chip has a second region that overlaps the first region in the first direction and some of the second memory cells are in the second region.

20. The semiconductor memory device according to claim 19, wherein
the first memory chip has first bit lines extending in a second direction that crosses the first direction, a first set of first memory cells electrically connected to the first bit lines and formed above the first bit lines in the first direction, second bit lines extending in the second direction, and a second set of first memory cells electrically connected to the second bit lines and formed above the second bit lines in the first direction, and
the second memory chip has third bit lines extending in the second direction into the second region, a first set of second memory cells electrically connected to the third bit lines and formed in the second region above the third bit lines in the first direction, fourth bit lines extending in the second direction into the second region, and a second set of second memory cells electrically connected to the fourth bit lines and formed in the second region above the fourth bit lines in the first direction.
